(19) United States
(12) Patent Application Publication
(10) Pub. No.: US 2008/0123321 A1
(43) Pub. Date: May 29, 2008

(54) BACKLIGHT UNIT

(76) Inventors: Hung-Huei Hsu, Hsinchu (TW); Wen-Yuan Chuang, Hsinchu (TW)

Correspondence Address: NORTH AMERICA INTELLECTUAL PROPERTY CORPORATION, P.O. BOX 506, MERRIFIELD, VA, 22116, US

(21) Appl. No.: 11/626,381

(22) Filed: Jan. 24, 2007

(30) Foreign Application Priority Data
Nov. 2, 2006 (TW) 095140577

(51) Int. Cl. F21V 9/14; H01L 51/50

(52) U.S. Cl. 362/19

(57) ABSTRACT

A backlight unit is disclosed. The backlight unit contains a light-generating device and a polarization conversion apparatus, wherein the polarization conversion apparatus acts as the top substrate of the light-generating device. The polarization conversion apparatus converts natural light originating from the light-generating device into polarized light of a predetermined polarization. Therefore, the backlight unit of the present invention is capable of providing polarized light.

### BACKGROUND OF THE INVENTION

1. Field of the Invention

The present invention is related to a backlight unit, and particularly to a backlight unit capable of providing polarized light and having the advantages of full-light exploitation, and being thin and lightweight.

2. Description of the Prior Art

A backlight unit is one of the key components of a liquid crystal display (LCD). Since a LCD panel does not generate light itself, the backlight unit is responsible for providing sufficient light and uniform luminance for the LCD panel. At the present time, LCDs are broadly used in several electrical products, such as monitors, notebooks, digital cameras, and overhead projectors. Consequently, the demand of backlight units and their related components is growing.

Referring to FIG. 1, FIG. 1 is a schematic diagram of a conventional LCD, which includes a LCD panel 10, a bottom polarizer 12, a top polarizer 14, and a backlight unit 16. The LCD panel 10 further has glass substrates, alignment films, a liquid crystal layer, and a color filter array. To display an image, a bias is applied to change the orientation of the liquid crystal. In company with the polarizers, lights generated by the backlight unit 16 will be changed to display images. The polarizers used in conventional LCDs convert natural light to polarized light by absorbing light polarized in one direction and passing light polarized in another direction. However, the mechanism of the conventional absorptive polarizer fails to take full advantage of light generated from the backlight unit. In addition, each polarizer has a pair of substrates. Accordingly, the conventional LCDs have a substantial thickness, which goes against the tendency of reducing weight and volume of the LCDs.

### SUMMARY OF THE INVENTION

Therefore, a primary objective of the present invention is to provide a backlight unit, and particularly, to provide a backlight unit that uses polarizers, retardation films, or combinations thereof as the top substrate of the backlight unit. The backlight unit has the advantages of full-light exploitation, being thin and lightweight, and providing polarized light.

According to the invention, a backlight unit is provided. The backlight unit has a bottom substrate, a light-generating device disposed on the bottom substrate, and a polarization conversion apparatus disposed on the light-generating device. The polarization conversion apparatus acts as a top substrate of the light-generating device to convert light from the light-generating device into polarized light. Therefore, the backlight unit of the present invention has a reduced thickness.

The backlight unit of the present invention provides polarized light and has a reduced thickness in keeping with future requirements of the LCD industry.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a conventional LCD.

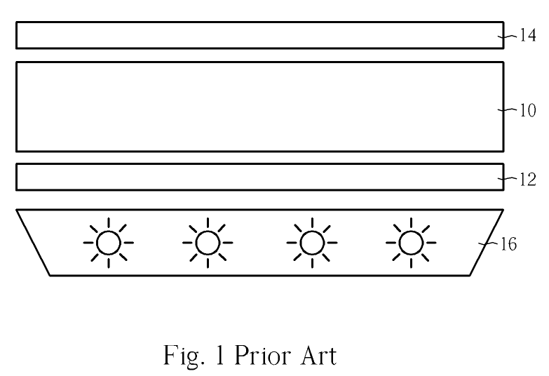

FIG. 2 is a schematic diagram illustrating a backlight unit according to a first embodiment of the present invention.

FIG. 3 is schematic diagram of another backlight unit according to a second embodiment of the present invention.

FIG. 4 shows a backlight unit according to a third embodiment of the present invention.

FIG. 5 is a schematic diagram illustrating a backlight unit according to a fourth embodiment of the present invention.

FIG. 6 is a schematic diagram illustrating a backlight unit according to a fifth embodiment of the present invention.

FIG. 7 is a schematic diagram illustrating another backlight unit according to a sixth embodiment of the present invention.

### DETAILED DESCRIPTION

In the following detailed description, reference is made to the accompanying drawings, which form a part of this application. The drawings show, by way of illustration, specific embodiments in which the invention may be realized. It is to be understood that other embodiments may be utilized and structural changes may be made without departing from the scope of the present invention.

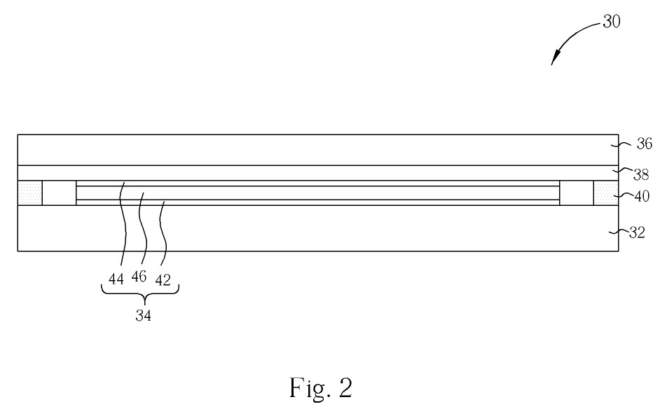

FIG. 2 is a schematic diagram illustrating a backlight unit according to a first embodiment of the present invention. FIG. 2 shows a backlight unit 30 that includes a bottom substrate 32, a light-generating device 34 disposed on the bottom substrate 32, a reflective polarizer 36 positioned on a surface of the light-generating 34 device opposite to the bottom substrate 32, a sealing material 40 disposed between the reflective polarizer 36 and the bottom substrate 32, and an optical film 38 disposed between the reflective polarizer 36 and the light-generating device 34. The optical film 38 may be a high-transmission retardation film, a depolarizer or other kinds of optical films capable of converting the polarized direction of a light. It should be noted that the reflective polarizer 36 and the optical film 38 of the present invention are capable of both converting a light polarization direction to provide polarized light and acting as the top substrate of the light-generating device 34 for protection. Furthermore, the reflective polarizer 36 and the optical film 38 also have respective substrates protecting themselves. The light-generating device 34 of the first preferred embodiment may be an organic light-emitting diode (OLED) device that has a bottom electrode (cathode) 42 disposed on a surface of the lower substrate 32, a top electrode (anode) 44, and an organic light-emitting layer 46 disposed between the top electrode 44 and the bottom electrode 42. In addition, the top electrode 44 has a transparent conductive layer comprising materials of indium tin oxide (ITO) or indium zinc oxide (IZO). The organic light-emitting layer 44 further includes a hole injection layer, a hole transport layer, a light-emitting layer, an electron transport layer, and an electron injection layer. The bottom electrode 42 may be a metal layer or an alloy layer, such as an Al—Mg alloy layer, an Al—Li alloy layer, or an Al/aluminum fluoride layer. Additionally, the bottom electrode 42 may act as a bottom substrate of the backlight unit 30 depending on the type of the OLED device.

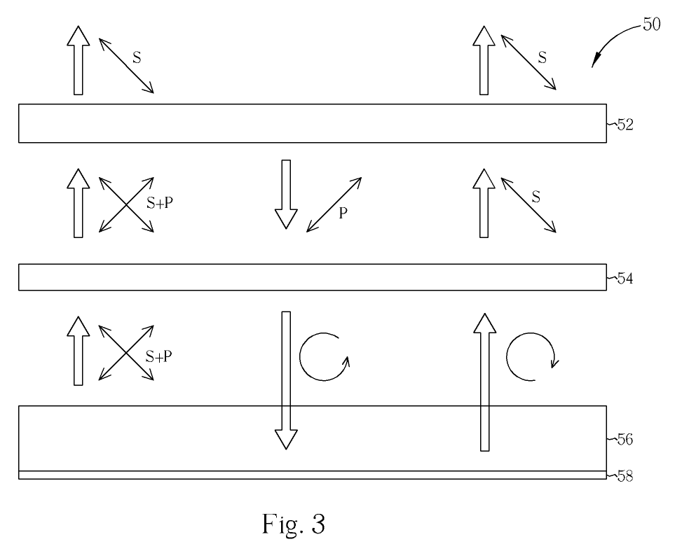

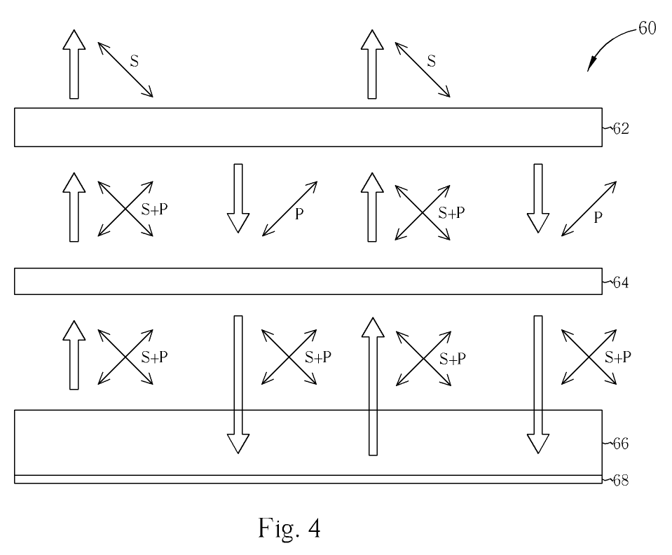

FIG. 3 and FIG. 4 illustrate the mechanism of the backlight unit of the present invention for providing light polarized in a predetermined direction. As shown in FIG. 3, FIG. 3 is schematic diagram illustrating another backlight unit 50 according to a second embodiment of the present invention. The backlight unit 50 includes a reflective polarizer 52, a wide range quarter-wave retardation film 54 (represented as λ/4 retardation film in the following, where λ indicates the wavelength of light), an OLED device 56, a reflective layer 58 comprising metal or alloy that acts as a bottom substrate of the backlight unit 50, and a sealing material (not shown) disposed around the OLED device 56. The reflective polarizer 52 is capable of selecting the natural light generated from the OLED device 56 and allowing polarized light of a particular polarized direction to pass through. Light of other polarized directions will be reflected. For instance, the reflective polarizer 56 of the second preferred embodiment may allow linear s-polarized light to pass through while reflecting p-polarized light. The following will illustrate the mechanism of the backlight unit 50 for providing polarized light. Natural light generated from the OLED device 56 includes linear polarized light, s-polarized light and p-polarized light. When natural light passes through the wide range λ/4 retardation film 54 and strikes the reflective polarizer 52, the reflective polarizer 52 allows s-polarized light to pass through while reflecting p-polarized light. The wide range λ/4 retardation film 54 converts the reflected p-polarized light into the left-hand circularly polarized light. The left-hand circularly polarized light reflects on a surface of the reflective layer 58 and is converted into the right-hand circularly polarized light. Again, the wide range λ/4 retardation film 54 converts the right-hand circularly polarized light into the s-polarized light that passes through the reflective polarizer 52 eventually. As noted above, the backlight unit 50 provides polarized light by the cooperation of the reflective polarizer 52, the wide range λ/4 retardation film 54, and the reflective layer 58. This increases the light exploitation of the backlight unit 50. Furthermore, although the second preferred embodiment uses a wide range λ/4 retardation film 54 capable of converting linear p-polarized light into left-hand circularly polarized light as an example, other types of wide range λ/4 retardation film having different converting properties may be used in the present invention. The converting relationship between linear polarized light and circular polarized light is determined by the wide range λ/4 retardation film. For instance, wide range λ/4 retardation film capable of converting p-polarized light into right-hand circularly polarized light may also be used in the present invention. Moreover, the second preferred embodiment takes a backlight unit capable of providing s-polarized light as an example, but other types of backlight units capable of providing predetermined polarized light are allowable, for instance, a backlight unit capable of providing linear p-polarized light or circular polarized light. The reflective polarizer and the retardation film may be replaced to provide different types of polarized light.

As described above, FIG. 4 shows a backlight unit 60 according to a third preferred embodiment of the present invention. The backlight unit 60 includes a reflective polarizer 62, a depolarizer 64, an OLED device 66, a reflective layer 68 acting as a bottom substrate of the backlight unit 60, and a sealing material (not shown) positioned around the OLED device 66. In the third preferred embodiment, the reflective polarizer 62 allows s-polarized light to pass through but reflects the p-polarized light. Natural light generated from the OLED device 66 includes p-polarized light and s-polarized light. When natural light passes through the depolarizer 64 and strikes the reflective polarizer 62, the reflective polarizer 62 allows s-polarized light to pass through while reflecting p-polarized light. The reflected p-polarized light goes back to the depolarizer 64 and is depolarized into a mixed light including p-polarized light and s-polarized light. Then, the mixed light reflects on a surface of the reflective layer 68 and goes to the depolarizer 64 and the reflective polarizer 62 for a second selection. Again, s-polarized light is selected from the mixed light and p-polarized light is reflected for further conversion and selection. With the combination of the reflective polarizer 62, the depolarizer 64 and the reflective layer 68, the backlight unit 60 has an improved light exploitation. In addition, although the third preferred embodiment takes a backlight unit capable of providing s-polarized light as an example, other types of backlight units capable of providing predetermined polarized light are allowable, for instance, a backlight unit capable of providing linear p-polarized light or circular polarized light.

In brief, the backlight unit of the present invention utilizes a reflective polarizer, a λ/4 retardation film, a depolarizer or other optical films that act as a top substrate of the backlight unit to reduce the thickness of the backlight unit. In addition, the backlight unit of the present invention has the advantages of full-light exploitation, and an improved polarized light converting rate.

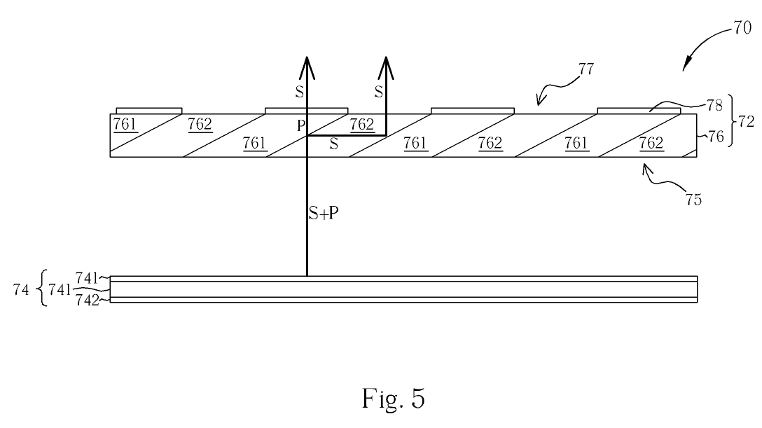

In addition to the above-mentioned embodiments, the present invention further discloses several more embodiments as follows. The following embodiments use a polarization conversion apparatus that converts natural light generated from the light-generating device into polarized light for radiation. Please refer to FIG. 5 through FIG. 7. FIG. 5 is a schematic diagram illustrating a backlight unit 70 according to a fourth embodiment of the present invention. The backlight unit 70 has a polarization conversion device 72 and a light-generating device 74. The light-generating device 74 may be an OLED device that comprises a top electrode (anode) 741, a bottom electrode (cathode) 742, and an organic light-emitting layer 743 disposed between the top electrode 741 and the bottom electrode 742. The bottom electrode 742 is made of metal and is capable of reflecting light to increase light exploitation. The bottom electrode 742 may also act as a bottom substrate of the backlight unit 70. The polarization conversion device 72 further includes a polarization separation film 76 and a plurality of retardation films 78. The polarization conversion device 72 converts natural light generated from the light-generating device 74 into a predetermined polarized light. The polarization separation film has a light entrance plane 75 and the polarization separation film 76 is constructed by a plurality of low-refractive index structures (first structures) 761 and a plurality of high-refractive index structures (second structures) 762 arranged next to each other. Each retardation film 78 is respectively disposed on a surface 77 of each low-refractive index structure 761 opposite to the light-generating device 74. In the fourth embodiment, the retardation films 78 comprise wide range half-wave retardation films (represented as λ/2 retardation film in the following, where λ indicates the wavelength of light) to convert polarized light between p-polarized light and s-polarized light. Natural light generated from the light-generating device 74 includes p-polarized light and s-polarized light. When natural light strikes the high-refractive index structures 762, p-polarized light passes through the low-refractive index structure 761, and s-polarized light reflects on an interface between the high-refractive index structure 762 and the low-refractive index structure 761. The reflected s-polarized light reflects again on another interface between the high-refractive index structures 762 and the low-refractive index structure 761, and radiates from the surface 77 of the low-refractive index structures 761 opposite to the light-generating device 74. P-polarized light passing through the low-refractive index structure 761 is converted into s-polarized light by the retardation film 76 and radiates from the surface 77 of the low-refractive index structures 761 opposite to the light-generating device 74. Therefore, natural light generated from the light-generating device 74 is converted into polarized light having a predetermined polarization direction. This increases the light exploitation of the backlight unit 70. In addition, the third embodiment takes a backlight unit capable of providing s-polarized light as an example, but other types of backlight units capable of providing predetermined polarized light are allowable, for instance, a backlight unit capable of providing linear p-polarized light or circular polarized light. The polarization separation film and the retardation film may be replaced to provide different types of polarized light.

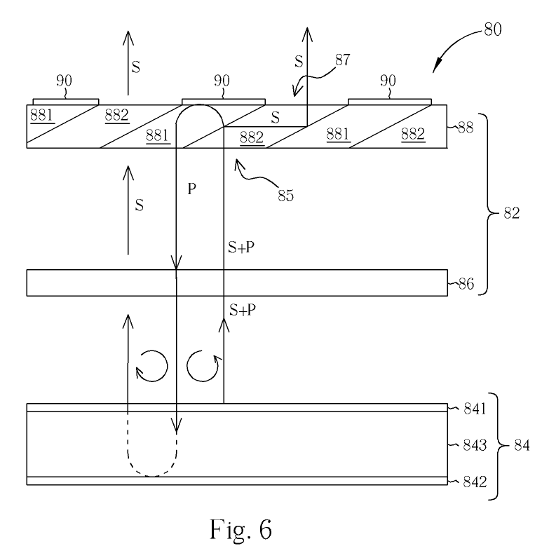

Based on the concept of the present invention, the present invention further discloses another backlight unit 80 according to a fifth embodiment of the present invention. Referring to FIG. 6, the backlight unit 80 includes a polarization conversion apparatus 82 and a light-generating device 84. The polarization conversion apparatus 82 further has a retardation film 86, a polarization separation film 88 disposed on a surface of the retardation film 86 opposite to the light-generating device 84, and a plurality of reflective films 90. The light-generating device 84 may be an OLED device that comprises a top electrode (anode) 841, a bottom electrode (cathode) 842, and an organic light-emitting layer 843 disposed between the top electrode 841 and the bottom electrode 842. In addition, the top electrode 841 has a transparent conductive layer comprising materials of ITO or IZO. The organic light-emitting layer 843 further includes a hole injection layer, a hole transport layer, a light-emitting layer, an electron transport layer, and an electron injection layer. The bottom electrode 842 may be a metal layer or an alloy layer, such as an Al—Mg alloy layer, an Al—Li alloy layer, or an Al/aluminum fluoride layer. Additionally, the material of the bottom electrode 842 includes metal and is capable of reflecting light to increase light exploitation. Moreover, the bottom electrode 842 also acts as a bottom substrate of the backlight unit 80. The polarization separation film has a light entrance plane 85 and the polarization separation film 88 is constructed by a plurality of low-refractive index structures (first structures) 881 and a plurality of high-refractive index structures (second structures) 882 arranged next to each other. Each reflective film 90 is respectively disposed on a surface 87 of each low-refractive index structure 881 opposite to the light-generating device 84. In the fifth embodiment, the retardation films 86 comprise λ/4 retardation film. Natural light generated from the light-generating device 84 includes p-polarized light and s-polarized light. When natural light strikes the high-refractive index structures 882, p-polarized light passes through the low-refractive index structure 881, and s-polarized light reflects on an interface between the high-refractive index structure 882 and the low-refractive index structure 881. The reflected s-polarized light reflects again on another interface between the high-refractive index structures 882 and the low-refractive index structure 881, and radiates from the surface 87 of the polarization separation film 88 opposite to the light-generating device 84. P-polarized light passing through the low-refractive index structure 881 is reflected on a surface of the reflective film 90 and is converted by the retardation film 86 into the left-hand circularly polarization light. Then, the left-hand circularly polarization light is reflected on a surface of the bottom electrode 842 and is converted into right-hand circularly polarized light. Thereafter, the right-hand circularly polarized light is converted into s-polarized light and radiates from the backlight unit 80. As illustrated above, the cooperation of polarization separation film 88 and the retardation film 86 effectively increases the light exploitation of the backlight unit 80. Furthermore, although the fifth embodiment uses a λ/4 retardation film, which is capable of converting linear p-polarized light into left-hand circularly polarized light as an example, other types of λ/4 retardation film having different converting properties may be used in the present invention. The converting relationship between linear polarized light and circular polarized light is determined by the λ/4 retardation film. For instance, wide range λ/4 retardation film capable of converting p-polarized light into right-hand circularly polarized light may also be used in the present invention. Moreover, the fifth embodiment takes a backlight unit capable of providing s-polarized light as example, but other types of backlight units capable of providing predetermined polarized light are allowable, for instance, a backlight unit capable of providing linear p-polarized light or circular polarized light. The polarization separation film and the retardation film may be replaced to provide different types of polarized light.

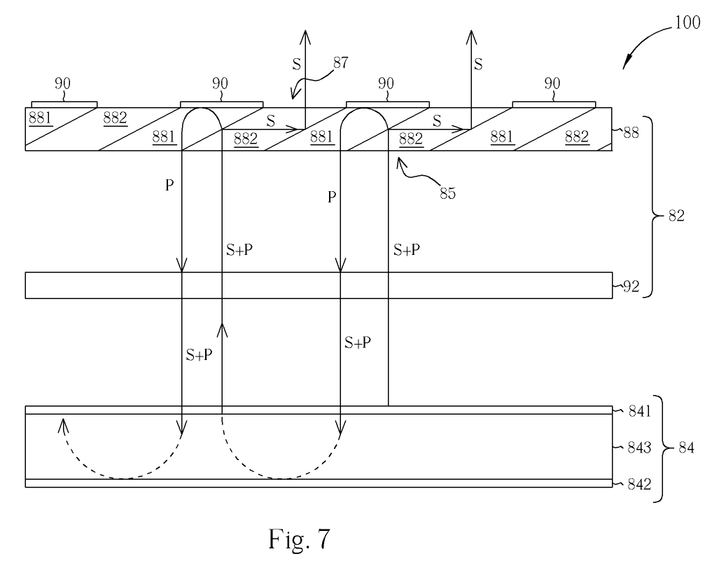

Referring to FIG. 7, FIG. 7 is a schematic diagram illustrating another backlight unit 100 according to a sixth embodiment of the present invention. The same members as those of the fifth embodiment shown in FIG. 6 are identified by the same reference numerals and the description thereof will be omitted herein. However, the retardation film of the fifth embodiment is replaced by a depolarizer 92. Natural light generated from the light-generating device 84 passes through the depolarizer 92 and strikes the polarization separation film 88. S-polarized light separated by the polarization separation film 88 reflects twice and radiates from the surface 88. P-polarized light separated by the polarization separation film 88 reflects on a surface of the reflective film 90 and is depolarized by the depolarizer 92 into a mixed light including p-polarized light and s-polarized light. Then, the mixed light reflects on a surface of the bottom electrode 842 and goes to the depolarizer 92 and the polarization separation film 88 for a second selection. Once again, s-polarized light is selected from the mixed light and p-polarized light is reflected for further conversion and selection. With the cooperation of the polarization separation film 88, the depolarizer 92, and the bottom electrode, the backlight unit 100 has an improved light-exploitation. In addition, although the sixth embodiment takes a backlight unit capable of providing s-polarized light as an example, other types of backlight units capable of providing predetermined polarized light are allowable, for instance, a backlight unit capable of providing linear p-polarized light or circular polarized light. The polarization separation film may be replaced to provide polarized light of different polarization properties.

The above embodiments of the present invention use an OLED device as the light-generating device but other light-generating devices are allowable. For instance, a light emitting device (LED), a planar light including inert gas, or other self-generating lights may be utilized in the present invention. The sealing material (not shown) of the present invention is positioned around the light-generating device for protection. Furthermore, the polarizer, the polarization separation film or the retardation film may be replaced to convert natural light into polarized light of different polarization properties.

As illustrated by the above-mentioned embodiments, the present invention provides a backlight unit capable of providing polarized light. The backlight unit of the present invention uses the polarizer, the retardation film, or other optical films acting as the top substrate of the backlight unit. Therefore, the backlight unit of the present invention has a reduced thickness and is capable of increasing light exploitation and reducing power consumption.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A backlight unit, comprising:
a bottom substrate;
a light-generating device disposed on the bottom substrate; and
a polarization conversion apparatus disposed on the light-generating device, the polarization conversion apparatus acting as a top substrate of the light-generating device to convert light from the light-generating device into polarized light.

2. The backlight unit of claim 1, wherein the polarization conversion apparatus further comprises a polarization film comprising:
a plurality of first structures and a plurality of second structures arranged next to each other, the first structures and the second structures having differently respective refractive indexes; and
a plurality of retardation films, each retardation film being located on a surface of each first structure opposite to the light-generating device.

3. The backlight unit of the claim 2, wherein the retardation films comprise half-wave retardation films.

4. The backlight unit of claim 3, wherein the refractive index of the first structures is greater than the refractive index of the second structures.

5. The backlight unit of claim 4, wherein the light-generating device further comprises:
a top electrode;
a bottom electrode; and
an organic light-emitting layer disposed between the top electrode and the bottom electrode.

6. The backlight unit of claim 1, wherein the polarization conversion apparatus further comprises:
a depolarizer; and
a polarization separation film disposed on a surface of the depolarizer opposite to the light-generating device, the polarization separation film comprising:
a plurality of first structures and a plurality of second structures arranged next to each other, the first structures and the second structures having differently respective refractive indexes; and
a plurality of reflective films, each reflective film being located on a surface of each first structure opposite to the light-generating device.

7. The backlight unit of claim 6, wherein the refractive index of the first structures is greater than the refractive index of the second structures.

8. The backlight unit of claim 7, wherein the light-generating device further comprises:
a top electrode;
a bottom electrode; and
an organic light-emitting layer disposed between the top electrode and the bottom electrode.

9. The backlight unit of claim 1, wherein the polarization conversion apparatus further comprises:
a retardation film; and
a polarization separation film disposed on a surface of the retardation film opposite to the light-generating device, the polarization separation film comprising:
a plurality of first structures and a plurality of second structures arranged next to each other, the first structures and the second structures having differently respective refractive indexes; and
a plurality of reflective films, each respective film being located on a surface of each first structure opposite to the light-generating device.

10. The backlight unit of claim 9, wherein the retardation films comprise quarter-wave retardation films.

11. The backlight unit of claim 10, wherein the refractive index of the first structures is greater than the refractive index of the second structures.

12. The backlight unit of claim 11, wherein the light-generating device further comprises:
a top electrode;
a bottom electrode; and
an organic light-emitting layer disposed between the top electrode and the bottom electrode.

13. The backlight unit of claim 1, wherein the polarization conversion apparatus further comprises:
a reflective polarization film; and
a retardation film disposed between the reflective polarization film and the light-generating device.

14. The backlight unit of claim 13, wherein the retardation film comprises a quarter-wave retardation film.

15. The backlight unit of claim 14, wherein the light-generating device further comprises:
a top electrode;
a bottom electrode; and
an organic light-emitting layer disposed between the top electrode and the bottom electrode.

16. The backlight unit of claim 1, wherein the polarization conversion apparatus further comprises:
a reflective polarization film; and
a depolarizer disposed between the reflective polarization film and the light-generating device.

17. The backlight unit of claim 16, wherein the light-generating device further comprises:
a top electrode;
a bottom electrode; and
an organic light-emitting layer disposed between the top electrode and the bottom electrode.
